(19) United States
(12) Patent Application Publication
(10) Pub. No.: US 2003/0164502 A1
(43) Pub. Date: Sep. 4, 2003

(54) Optoelectronic component and a method for producing the same

(76) Inventors: Johannes Baur, Laaber (DE); Uwe Strauss, Bad Abbach (DE); norbert Linder, Wenzenbach (DE); Reinhard Sedlmeier, Neutraubling (DE); Ernst Nirschl, Wenzenbach (DE)

Correspondence Address: FISH & RICHARDSON PC, 225 FRANKLIN ST, BOSTON, MA, 02110, US

(21) Appl. No.: 10/296,195

(22) PCT Filed: Apr. 6, 2001
(86) PCT No.: PCT/DE01/01369

(30) Foreign Application Priority Data
May 23, 2000 (DE) 1002544839
Feb. 15, 2001 (DE) 10107472.7

(51) Int. Cl. H01L 29/22; H01L 31/0256; H01L 31/0296

(52) U.S. Cl. 257/78

(57) ABSTRACT

Optoelectronic component and method for producing the same To improve the permeability of a contact layer (6) of a light-emitting diode (1), it is proposed to provide the contact layer (6) with openings (8) through which photons generated in a pn junction (5) can escape. Small spheres, for example of polystyrene, are used to produce the openings (8). FIG. 1

The invention concerns an optoelectronic component comprising a radioparent contact surface on a semiconductor surface based on InₓAl_{y}Ga₁₋ₓ₋N, where 0≦x≦1.0≦y≦1 and x+y≦1.

The invention further concerns a method for producing a radioparent contact layer on a semiconductor surface of a semiconductor.

In epitaxially grown light-emitting diodes (LEDs) based on the material system InAlGaN, the lateral spread of current in the p-doped layer ranges from a few tenths of a micron to a few microns. It is therefore customary, in making the connection contacts, to deposit contact layers that cover the entire surface of the semiconductor in order to ensure uniform current injection into the active layer of the LED. However, these areally deposited contact layers absorb a substantial portion of the light exiting through the semiconductor surface.

Heretofore, very thin, semitransparent contact layers have been used for the connection contacts. Such semitransparent contact layers on an InAlGaN-based semiconductor chip are known from U.S.Pat. No. 5,767,581 A. To ensure high transparency for the connection contacts, the semitransparent layers must be made as thin as possible. Running counter to this is the need for sufficient homogeneity, sufficient transverse conductivity and low contact resistance. Hence, the semitransparent contact layers used in conventional LEDs inevitably absorb the majority of the light exiting through the surface.

Moreover, under high thermal loads, known InAlGaN-based optoelectronic components having semitransparent contacts can fail due to degradation of the contact layer.

From DE 1 99 27 945 A1, it is further known to deposit a contact layer having a thickness of 1000 to 30,000 A on the p-doped layer of an InAlGaN-based LED. Openings with a width of 0.5 to 2 μm are made in this contact layer to improve the transmission of light therethrough.

Proceeding from this prior art, the object of the invention is to provide InAlGaN-based components that are suitable for optoelectronics and exhibit improved light decoupling and improved ageing behavior.

This object is accomplished according to the invention in that the contact layer comprises a plurality of mutually juxtaposed recesses and in that the thickness of the contact layer is greater than 5 nm and less than 100 nm.

Providing a plurality of recesses in the contact layer substantially increases the decoupling of light. This is because more light will pass through the contact layer at the locations where it is weakened or interrupted than at the locations where it has its full thickness. Since the contact layer is weakened and interrupted only locally, uniform injection into the active layer of the optical component is assured despite the improved decoupling of light from the contact layer.

The recesses are also advantageous with regard to the ageing behavior of the optoelectronic component. A p-doped layer of InAlGaN contains very small amounts of hydrogen, which diffuses to the interface between the contact layer and the InAlGaN layer when the optoelectronic component is in operation. If the contact layer is not permeable to hydrogen, then hydrogen collects at the interface and passivates the dopant. The contact resistance between the contact layer and the InAlGaN layer beneath it therefore increases under thermal loading. Thermal loads occur both during the operation of finished LEDs and during the processing of the wafer. However, hydrogen can escape through the weakened places in the contact layer and the contact resistance will still remain essentially constant.

The thickness of the contact layer is also important in this connection. To ensure that hydrogen is carried off, it is advantageous for the width of the webs between the recesses to be as small as possible. To make the interface between the contact layer and the p-doped layer as large as possible so as to achieve a low contact resistance, there should be a large number of recesses whose cross-sectional dimensions are on the order of the wavelength of the light emitted by the component. Hydrogen can escape from the underlying InAlGaN layer over the surface through a large number of recesses having very small cross-sectional dimensions. The thickness of the contact layer, however, should be many times smaller than the minimum cross-sectional dimensions of the recesses, so that a large number of closely juxtaposed recesses can be made in an exact pattern in the contact layer without the webs of the contact layer suffering etching damage that would impair their ability to carry current.

In a preferred embodiment, the recesses are openings that pass all the way through the contact layer.

In this embodiment, the hydrogen is guided around the contact layer and can escape unhindered from the InAlGaN layer located beneath the contact layer.

A further object of the invention is to provide a method for producing an optoelectronic component with improved light decoupling and improved ageing behavior.

This object is accomplished according to the invention by the fact that the contact layer is patterned with recesses by means of a layer of particles that do not fully cover the semiconductor surface.

The particles deposited on the semiconductor surface serve as a mask for the subsequent patterning of the contact surface. Of particular advantage is the fact that no photon-beam or electron-beam lithography need be used for this purpose.

Further advantageous embodiments of the invention are the subject matter of the dependent claims.

The invention is described in detail hereinbelow with reference to the appended drawing, wherein:

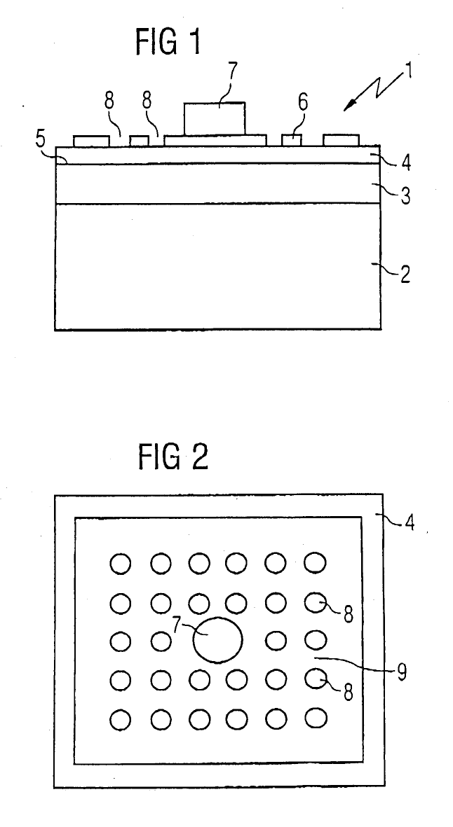

FIG. 1 is a cross section through an exemplary embodiment of an optoelectronic component;

FIG. 2 is a plan view of an optoelectronic component as depicted in FIG. 1;

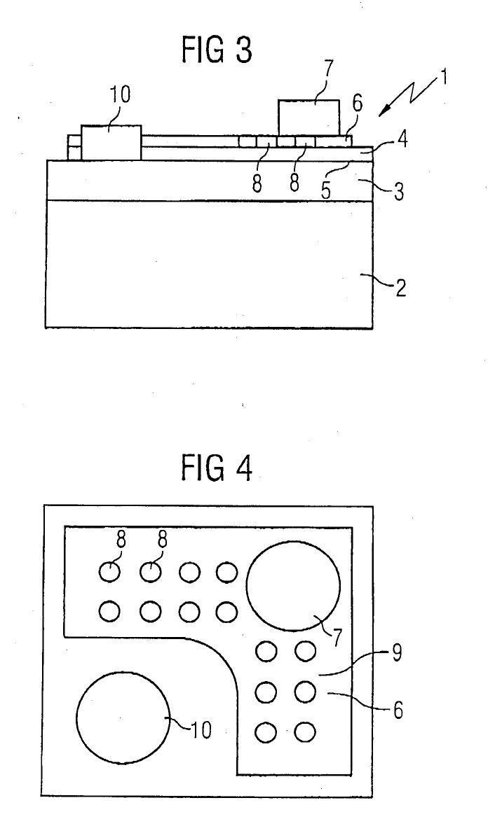

FIG. 3 is a cross section through a second exemplary embodiment of an optoelectronic component;

FIG. 4 is a plan view of the optoelectronic component depicted in FIG. 3;

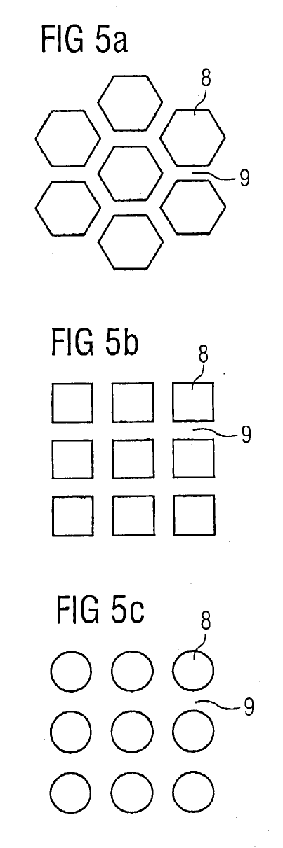

FIGS. 5a to 5c are various cross-sectional profiles of recesses made in the contact layers of the optoelectronic components;

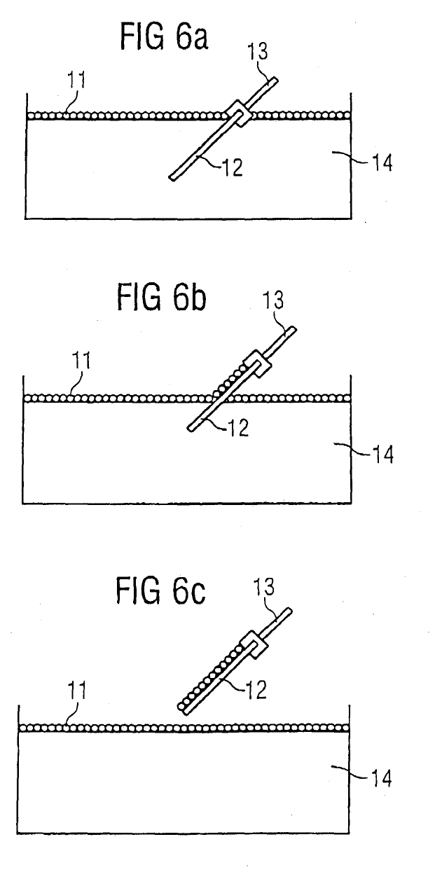

FIGS. 6a to 6c are various method steps for depositing spheres on a wafer to make the recesses in the contact layer of the optoelectronic component;

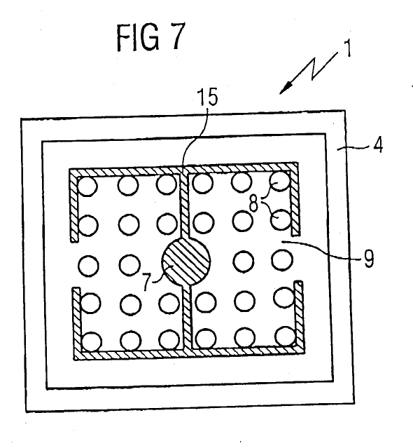

FIG. 7 is a plan view of a variant exemplary embodiment of the optoelectronic component, and

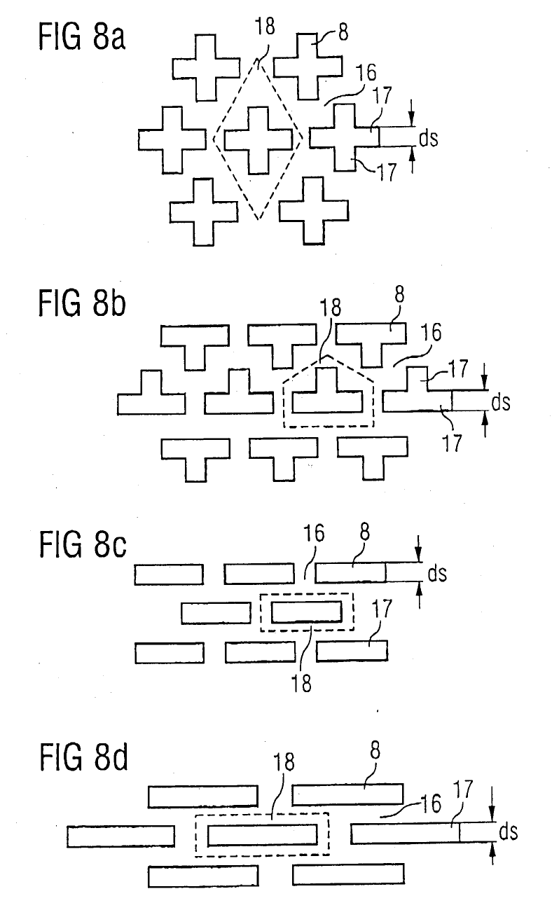

FIGS. 8a to 8d show various openings composed of slits in the contact layer of the optoelectronic component.

FIG. 1 is a cross section through an LED 1 comprising a conductive substrate 2. Deposited on the substrate 2 is an n-doped layer 3, contiguous to which is a p-doped layer 4. Both the n-doped layer 3 and the p-doped layer 4 are InAlGaN-based. This means that apart from production-induced impurities and added dopants, the composition of n-doped layer 3 and p-doped layer 4 is given by the formula:

InₓAl_{y}Ga_{1-x-y}N

where 0≦x≦1.0≦y≦1 and x+y≦1.

Between n-doped layer 3 and p-doped layer 4 there is created a pn junction 5, in which photons are generated when there is a flow of current. To enable current to flow across the pn junction 5, a contact layer 6 is provided on p-doped layer 4 and a connection contact 7 is placed thereon. The term “contact layer” should be understood in this connection to mean a layer that establishes an ohmic contact with an adjacent layer made of a semiconducting material. The term “ohmic contact” is to have the usual meaning ascribed to it in semiconductor physics.

Since LED 1 is an LED based on the material system InAlGaN, the lateral current spread in the p-doped layer 4 is in the range of a few tenths of a micron to a few microns. Contact layer 6 therefore extends over as much of the area of p-doped layer 4 as possible in order to ensure uniform current distribution over the pn junction 5. However, so that the photons generated in the pn junction 5 can exit the LED 1 with as little absorption as possible, openings 8 are made in contact layer 6. The cross-sectional dimension[s] of openings 8 are so selected as to be less than twice the lateral current spread in p-doped layer 2. Depending on the thickness of p-doped layer 4, the lateral current spread in p-doped layer 4 based on InAlGaN is between 1 and 4 μm.

On the other hand, during the operation of the LED 1, hydrogen from p-doped layer 4 must be prevented from accumulating along the interface with contact layer 6 and passivating the dopant—usually magnesium—at that location, since under thermal loading this would have the effect of increasing the contact resistance at the interface between contact layer 6 and p-doped layer 4. It is therefore advantageous to make the largest possible number of openings in contact layer 6, in order to conduct the hydrogen from the p-doped layer 4 over the surface as evenly as possible. The tendency, therefore, is to provide a large number of openings 8 having small cross-sectional dimensions. The cross-sectional dimensions of the openings 8 thus are preferably selected to be smaller than 3 μm, particularly smaller than 1 μm. If, in particular, the openings 8 are realized as circular, the diameter of the openings 8 is selected to be smaller than 3 μm, preferably smaller than 1 μm. On the other hand, to obtain sufficiently high decoupling of light through the contact layer 6, the cross-sectional dimensions of the openings 8 must be larger than ¼ the wavelength of the photons generated by the LED 1 in the openings 8. The cross-sectional dimensions of the openings 8 should therefore be at least 50 nm.

If the permeability requirements for the contact layer 6 are not too high, the openings 8 can be replaced by depressions in the contact layer 6. In this case, however, the remaining thickness of material should be so very small that the photons generated in the pn junction 5 can exit through the contact layer 6. In addition, hydrogen must be able to pass through the material that remains. This is the case in particular if the remaining material is hydrogen-permeable. Such materials are, for example, palladium or platinum.

A further option is to make the contact layer 6 itself so thin that said contact layer 6 is semitransparent to photons and permeable to hydrogen.

FIG. 2 is a plan view of the LED 1 of FIG. 1. From FIG. 2 it is apparent that the openings 8 are distributed in an evenly spaced manner over the surface of the contact layer 6. To keep ohmic losses during the transport of current from connection contact 7 to the marginal areas of contact layer 6 as low as possible, the density of the openings 8 can increase outwardly, resulting in the presence of broad contact webs 9 near connection contact 7. In addition, the cross-sectional area of the openings 8 can be made to increase toward the edges of the contact layer 6. This measure also serves to ensure the most efficient possible transport of current from connection contact 7 to the edges of contact layer 6.

FIG. 3 shows a further exemplary embodiment of the LED 1. In this exemplary embodiment, the substrate 2 is realized as insulating. An additional connection contact 10 is therefore provided for n-doped layer 3. The p-doped layer 4 and contact layer 6 thus cover only a portion of n-doped layer 3. This can be recognized clearly from FIG. 4, in particular.

FIGS. 5a to 5c, finally, show various exemplary embodiments of the openings 8. The hexagonal cross-sectional shape of the openings 8 shown in FIG. 5a is especially advantageous, since this embodiment has a particularly high ratio of open to covered area. However, square or circular across-sectional areas can also be contemplated for the openings 8. If the openings 8 are realized as square or rectangular, the contact layer 6 has a net-like configuration when viewed across its surface.

The openings 8 are made by the standard lithographic processes. To avoid damaging the n-doped layer 3, the p-doped layer 4 and the substrate 2, it is necessary to use appropriate combinations of etching methods and contact metals for the contact layer 6 and the connection contact 10. Especially suitable for the contact layer 6 is palladium, which can be etched with a cyanide etchant in a wet chemical process. Platinum is another candidate for this purpose. In the case of throughpassing openings 8, the contact layer 6 can also be made of materials that are not intrinsically permeable to hydrogen. Such materials are, for example, Ag, Au, and alloys thereof. It is also conceivable for the contact layer 6 to be a layer of Pt or Pd with an additional layer of Au deposited thereon.

Both wet chemical etching processes and reactive ionic etching or backsputtering are basically suitable for use as the etching process. Regardless of the etching method, the thickness of the contact layer 6 should, if at all possible, be less than 100 nm, so that the webs of the contact layer 6 are not damaged by the etching operation, thus impairing the ability to conduct current evenly. This problem arises in particular when an especially large number of openings 8 with a diameter of less than 3 μm, particularly 1 μm, are to be made in the contact layer 6. In this case it is especially important that the webs of contact layer 6 between the openings 8 remain as intact as possible so as to guarantee reliable current conduction. A large number of openings 8 in contact layer 6 that have a diameter of less than 3 μm, particularly 1 μm, is especially favorable for conducting hydrogen from the p-doped layer 4 uniformly over the contact layer 6.

Another factor that argues in favor of thicknesses below 100 nm is adjustment of the etching depth. To ensure that the openings 8 are etched out completely, it is generally necessary to select the etching time so that the etching depth in the material of the contact layer 6 is, for example, more than 10% greater than the thickness of the contact layer 6. If, however, the etching rate of the p-doped layer is higher than the etching rate of the contact layer 6, if the contact layer 6 is more than 100 nm thick the p-doped layer 4 may be etched away completely beneath the openings 8 in the contact layer 6. It is therefore advantageous not to allow the contact layer 6 to become thicker than 100 nm.

If precision requirements for the etching process are particularly rigorous, the thickness of the contact layer 6 should be less than 50 nm, preferably 30 nm.

In wet chemical etching, in particular, there is also the problem of back-etching of the layer of photosensitive resist used as a mask. As a consequence, patterns with a pattern size in the 1 μm range can be etched reliably only if the thickness of the contact layer to be etched is much smaller than the pattern size.

Backsputtering with argon ions is particularly well suited for especially small openings 8 in the contact layer 6. The etching rate is only about 5 nm/min, however. When the contact layer 6 is more than 100 nm thick, the etching time becomes so long that the photosensitive resist used as a mask is difficult to remove from the surface of the contact layer 6.

It should be noted that when the openings 8 are etched into the contact layer 6, indentations can also be etched deliberately into the p-doped layer 4. These indentations can also be realized as lens-shaped. The resulting inclined flanks or rough surfaces can further improve the decoupling of light.

As illustrated in FIGS. 6a to c, the openings 8 can also be made by means of small spheres 11, for example polystyrene spheres less than 1 μm in diameter. This method has the advantage that it can be used to produce openings 8 in the contact layer 6 that are too small to be made by the standard photo technique and ordinary etching methods. To this end, a wafer 12 with the LED 1 is immersed by means of a holder 13 in a liquid 14 on whose surface floats a single layer of the spheres 11 to be deposited. The density of the spheres 11 on the p-doped layer 4 is determined by the density of the spheres 11 on the surface of the liquid. A base can be added to lower the surface tension of the liquid and prevent clumping. The wafer 12 is immersed completely and then slowly withdrawn. The spheres 11 then adhere to the surface of the p-doped layer 4. The statistical distribution of the spheres 11 on the surface of the p-doped layer 4 is advantageous to the extent that interference effects are prevented when radiation passes through the contact layer 6. A statistical mixture of spheres of different diameters can be used to prevent such interference effects during the passage of radiation through the contact layer 6.

The spheres 11 can also, however, be distributed on the surface of the p-doped layer 4 so that the density of the spheres 11 increases toward the edges of the p-doped layer 4.

When the coverage density of the surface of the p-doped layer 4 is high, the contact points between the spheres can be eliminated in an additional method step by reducing the radii of the spheres, for example by plasma etching in ionized oxygen, thereby creating between the spheres unoccupied webs through which vapor deposition can be performed on the surface of the p-doped layer 4. Vapor deposition of a suitable metal then results in a coherent contact layer 6. In a variant embodiment of the method, the contact layer 6 is first vapor-deposited on the p-doped layer 4 and the entire monolayer of spheres 11 is then deposited on the contact layer 6. The contact layer 6 is then removed from unoccupied areas by backsputtering or plasma etching.

Finally, the spheres 11 are removed mechanically, for example by means of a solvent in an ultrasonic bath, or chemically, for example by dissolving them in an etching solution.

It should be noted that the spheres 11 can be deposited with the aid of an adhesive layer that is placed on the surface of the p-doped layer 4 and is removed before the unoccupied surface undergoes vapor deposition.

To keep the voltage drop at the contact layer 6 to a minimum, in the exemplary embodiment shown in FIG. 7 a conductive path 15 is fabricated on the contact layer 6 to facilitate the distribution of current in the contact layer 6.

This is also demonstrated by the measurements described below. An InGaN-based LED 1 on a SiC substrate 2 was used for the measurements. The emission wavelength of the LED 1 was 460 nm. The size of the LED 1 was 260×260 μm. The connection contact 7 was made of Au and had a thickness of 1 μm and a diameter of 100 μm. The contact layer 6, of Pt, was 6 nm thick. The LEDs 1 were installed in a package and measured with a current load of 20 mA. An LED with a transparent contact layer covering its surface served as a reference.

Compared to that LED, the luminous power of the LED 1 whose contact layer 6 had the pattern shown in FIG. 2 was 5% better. The forward voltage was 30 mV higher, however. The higher forward voltage is a result of the lower transverse conduction of the contact layer 6 compared to the reference.

The luminous power of the LED with its contact layer 6 reinforced with a conductive path 15 was 3% better than that of the reference. In addition, the forward voltage was 50 mV lower. The exemplary embodiment shown in FIG. 7 therefore proved to be especially advantageous.

FIGS. 8a to 8d show a further variant of the openings 8 in the contact layer 6. The openings illustrated in FIGS. 8a to 8d are composed of elongated slits and are arranged so that the webs 16 present between the openings 8 form a net-like pattern whose meshes are the openings 8.

The openings 8 shown in FIG. 8a have a cross-shaped cross-sectional profile. In this case, each opening 8 is formed by two slits 17 arranged so as to intersect. The width d, of each slit 17 is twice the lateral current spread in the p-doped layer 4. The distance between openings 8 is so selected that the webs 16 remaining between the openings 8 still have sufficient conductivity to distribute the current over the contact layer 6. In addition, care should be taken to ensure that the interface between the contact layer 6 and the p-doped layer 4 beneath it is not too small, so that the contact resistance between the contact layer 6 and the p-doped layer 4 beneath it does not become too high. A favorable arrangement was found to be one in which the minimum distance between openings 6 is greater than the width dₛ of the openings 8. Hence, based on a unit cell 18, the degree of coverage provided by the contact layer 6 can be calculated at 58%. The openings 8 therefore occupy 43% of the area of the contact layer 6 in this case.

It is also conceivable to provide T-shaped openings 8, as shown in FIG. 8b, or to realize the openings 8 as rectangular slits 17, as in FIG. 8c. In the case of the openings 8 shown in FIG. 8b, the degree of coverage provided by the contact layer 6 is 60%; with the exemplary embodiment illustrated in FIG. 8c, it is as high as 61%. The degree of coverage can be reduced sharply, however, if the slits 17 are lengthened increasingly. The smallest degree of coverage, i.e., 50%, occurs when the contact layer 6 corresponding to FIGS. 8c and 8d is patterned as a line lattice. Here, of course, there is a risk that large portions of the pn junction 5 will be cut off from the power supply if one of the contact webs 16 is interrupted. The configuration of openings 8 shown in FIG. 8a is especially advantageous, therefore, since it provides not only operational reliability, but also a high degree of openness.

Tests were also conducted to reveal the effect of the pattern of the contact layer 6 on the ageing behavior of the LED 1. For these tests, an n-doped layer 3 of AlGaN and GaN was precipitated onto a SiC substrate. On this layer, a layer p-doped with Mg was deposited by MOCVD [metal organic chemical vapor deposition]. On the same wafer, different contact layers 6 were constructed on the p-doped layers 4 of the individual chips. The cross-sectional dimensions of the contact layers 6 were between 200 μm×200 μm and 260 μm×260 μm. To simulate the ageing behavior of the LEDs 1, the chips for the LEDs 1 were tempered for 20 minutes at a temperature of 300° C.

A first chip for the LED 1, having a semitransparent Pt contact layer with a thickness of 20 nm, had the same forward voltage before and after tempering, based on a measurement accuracy of ±20 mV.

A further chip for the LED 1 was provided with a contact layer 6 made of Pt and 20 nm thick. In addition, the contact layer 6 of this chip was given a net-like pattern, with a mesh opening of 3 μm and a width for the remaining webs of the contact layer 6 of, again, 3 μm. This chip also had the same forward voltage before and after tempering, based on a measurement accuracy of ±20 mV. The same ageing behavior was also demonstrated by a chip whose contact layer 6 was composed, on the semiconductor side, of a first, 6-nm-thick layer of Pt and an additional, 20-nm-thick layer of Au, and whose contact layer was also given a net-like pattern.

By contrast, an average increase of 200 mV was found in chips for the LED 1 that were provided with full-area contact layers 6 composed, on the semiconductor side, of a 6-nm-thick layer of Pt and an additional, 100-nm-thick layer of Au.

These tests show that it is essential for stable ageing behavior that the hydrogen be able to escape via the contact layer 6. It is not necessary that the material used for the contact layer 6 be itself permeable to hydrogen, as long as the openings 8 are made in the contact layer 6.

It may be noted in conclusion that the improvement in luminous efficiency achieved by weakening the contact layer as described herein also occurs in laser diodes, especially in VCSELS [vertical cavity surface emitting lasers]. It is therefore advantageous to provide a locally weakened contact surface in laser diodes as well.

List of Reference Numerals

1 Light-emitting diode

2 Substrate

3 n-doped layer

4 p-doped layer

5 pn junction

6 Contact layer

7 Connection contact

8 Openings

9 Contact web

10 Connection contact

11 Spheres

12 Wafer

13 Holder

14 Liquid

15 Conductive path

16 Webs

17 Slit

18 Unit cell

1. An optoelectronic component comprising a radioparent contact layer (6) on a semiconductor surface based on InₓAl_{y}Ga_{1-x-y}N, where 0≦x≦1, 0≦y≦1 and x+y≦1, characterized in that
said contact layer (6) comprises a plurality of mutually juxtaposed recesses (8) and in that the thickness of said contact layer (6) is greater than 5 nm and less than 100 nm.

2. The component as recited in claim 1, characterized in that
the sum of the cross-sectional areas of said recesses (8) is greater than the area of the remaining contact layer (6).

3. The component as recited in claim 1 or 2, characterized in that
the cross-sectional areas of said recesses (8) are circular.

4. The component as recited in claim 1 or 2, characterized in that
said recesses (8) have hexagonal cross-sectional areas.

5. The component as recited in claim 1 or 2, characterized in that
said recesses (8) are formed by elongated slits (17).

6. The component as recited in claim 5, characterized in that
the webs (16) between said recesses (8) are interlinked.

7. The component as recited in any of claims 1 to 6, characterized in that
said recesses (8) are distributed in an evenly spaced manner over said contact layer (6).

8. The component as recited in any of claims 1 to 6, characterized in that
said recesses (8) are distributed in an unevenly spaced manner over said contact layer (6).

9. The component as recited in any of claims 1 to 6, characterized in that
the cross-sectional areas of said recesses (8) increase toward the edge of said contact layer (6).

10. The component as recited in any of claims 1 to 9, characterized in that
said recesses are openings (8) that pass all the way through said contact layer (6).

11. A method for producing a radioparent contact layer (6) on a semiconductor surface of a semiconductor, characterized in that
said contact layer (6) is patterned by means of a layer of particles (11) that do not cover the semiconductor surface completely, that comprise recesses (8), and that serve as a mask.

12. The method as recited in claim 11, characterized in that
said particles (11) are realized as spherical.

13. The method as recited in claim 11 or 12, characterized in that
said particles (11) are made of polystyrene.

14. The method as recited in any of claims 11 to 13, characterized in that
said particles (11) are used with outer dimensions of less than 1 μm.

15. The method as recited in any of claims 11 to 14, characterized in that
said particles (11) are floated onto the semiconductor surface by means of a liquid.

16. The method as recited in any of claims 11 to 15, characterized in that
said semiconductor surface is first covered with particles (11) and the material (6) used for metallization is deposited on said semiconductor surface.

17. The method as recited in claim 16, characterized in that
before the deposition of said material (6) used for metallization, said particles (11) are back-etched.

18. The method as recited in any of claims 11 to 15, characterized in that
said material (6) used for metallization is first precipitated on said semiconductor surface and said semiconductor surface is then covered with said particles (11), and said material (6) used for metallization is then removed from between said particles (11).

19. The method as recited in claim 18, characterized in that
the material (6) used for metallization that is not covered by said particles (11) is removed by backsputtering or plasma etching.

20. The method as recited in any of claims 11 to 19, characterized in that
after the patterning of said contact layer (6), said particles (11) are removed by means of solvents in an ultrasonic bath.

21. The method as recited in any of claims 11 to 19, characterized in that
after the patterning of said contact layer (6), said particles (11) are removed by being dissolved in an etching solution.
